(19) United States
(12) Patent Application Publication
(10) Pub. No.: US 2008/0296739 A1
(43) Pub. Date: Dec. 4, 2008

(54) Method of forming a thin film structure and stack structure comprising the thin film

(75) Inventors: Eun-ha Lee, Seoul (KR); Sang-moo Choi, Yongin-si (KR); Kwang-soo Seol, Suwon-si (KR); Sang-jin Park, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/005,371

(22) Filed: Dec. 27, 2007

(30) Foreign Application Priority Data
May 29, 2007 (KR) 10-2007-0052219

(51) Int. Cl. H01L 23/58; H01L 21/31

(52) U.S. Cl. 257/635; 438/778; 257/E23.001; 257/E21.24

(57) ABSTRACT

Provided is a method of forming a thin film structure and a stack structure comprising the thin film. The method may include forming a crystalline AlₓO_{y} film, forming a LaAlO film on the crystalline AlₓO_{y} film, and crystallizing the LaAlO film by annealing the LaAlO film.

### PRIORITY STATEMENT

This application claims priority under 35 U.S.C. §119 to Korean Patent Application No. 10-2007-0052219, filed on May 29, 2007, in the Korean Intellectual Property Office (KIPO), the entire contents of which are incorporated herein by reference.

### BACKGROUND

1. Field

Example embodiments relate to a method of forming a thin film structure and a stack structure comprising the thin film. Other example embodiments relate to a method of forming a LaAlO film structure and a stack structure comprising the LaAlO film.

2. Description of the Related Art

The compound LaAlO₃ has a pseudo-cubic perovskite crystal structure. Thus, when a thin film is formed on a single crystal LaAlO₃ substrate, the thin film may be epitaxially grown. The thin film grown on the single crystal LaAlO₃ substrate may have a relatively small area of grain boundary, and thus, may have improved characteristics compared to a thin film grown to be amorphous or polycrystalline.

Therefore, the single crystal LaAlO₃ substrate may be used as a substrate for forming a predetermined or given thin film in many fields. For example, the single crystal LaAlO₃ substrate may be used for growing a ferroelectric, e.g., plumbum-zirconate-titanate (PZT) (Pb—Zr—Ti—O). The single crystal LaAlO₃ substrate may be used as a substrate for a memory device, e.g., ferroelectric random access memories (FRAMs). Also, the single crystal LaAlO₃ substrate may be used as a substrate for an optical device and a super conductive device.

The LaAlO film may be epitaxially grown on a single crystal silicon substrate using a conventional method of growing the LaAlO film. However, the LaAlO film has not been epitaxially grown on a substrate (or a film) other than a silicon substrate. An LaAlO film grown on a substrate other than the silicon substrate may become a polycrystalline thin film having a random orientation in a subsequent annealing process. The LaAlO₃ substrate grown using a conventional method is more expensive than a silicon substrate or a glass substrate, and thus, may lead to increased manufacturing costs.

### SUMMARY

Example embodiments provide a method of forming a thin film structure, which includes epitaxially growing a LaAlO film regardless of the kind of substrate used. Example embodiments also provide a stack structure that includes the LaAlO film. If the LaAlO film can be epitaxially grown regardless of the kind of substrate used, the epitaxially grown LaAlO film (the epitaxial LaAlO film) may have a wider applicability than the conventional LaAlO₃ substrate.

According to example embodiments, a method of forming a thin film structure may include forming a crystalline AlₓO_{y} film, forming a LaAlO film on the crystalline AlₓO_{y} film, and crystallizing the LaAlO film by annealing the LaAlO film.

The AlₓO_{y} film may be a γ-Al₂O₃ film. The AlₓO_{y} film may be formed by annealing an amorphous AlₓO_{y} film. The amorphous AlₓO_{y} film may be annealed in a temperature range from about 700° C. to about 1200° C. The content of La may be greater than that of Al in the LaAlO film. The method may further include forming a capping film on the LaAlO film before annealing the LaAlO film after forming the LaAlO film. Forming the LaAlO film and forming the capping film may be performed through an in-situ press.

The AlₓO_{y} film may be a first AlₓO_{y} film and the capping film may be a second AlₓO_{y} film. The second AlₓO_{y} film may be an amorphous AlₓO_{y} film. The annealing may be performed in a temperature range of about 800° C. to about 1000° C.

At least a portion of the second AlₓO_{y} film and the LaAlO film may be intermixed during annealing.

According to example embodiments, a stack structure may include a crystalline AlₓO_{y} film, and a LaAlO film formed on the AlₓO_{y} film, wherein the LaAlO film may be identical to an epitaxially grown LaAlO film.

The AlₓO_{y} film may be a γ-Al₂O₃ film. The stack structure may further include a capping layer on the LaAlO film. The AlₓO_{y} film may be a first AlₓO_{y} film and the capping film may be a second AlₓO_{y} film. The second AlₓO_{y} film may be an amorphous AlₓO_{y} film. The crystalline AlₓO_{y} film may be formed on a nitride film. If example embodiments are used, a LaAlO film identical to an epitaxially grown LaAlO film may be formed regardless of the kind of substrate.

### BRIEF DESCRIPTION OF THE DRAWINGS

Example embodiments will be more clearly understood from the following detailed description taken in conjunction with the accompanying drawings. FIGS. 1A-8 represent non-limiting, example embodiments as described herein.

FIGS. 1A-1D are cross-sectional views illustrating a method of forming a LaAlO film structure according to example embodiments;

FIG. 2 is a transmission electron microscope (TEM) image of a sample of the stack of FIG. 1C;

FIG. 3 is a TEM image of the stack of FIG. 1D;

FIGS. 4 and 5 respectively are graphs showing auger electron spectroscopy (AES) analysis results of the samples of FIGS. 2 and 3;

FIG. 6 is a graph showing an X-ray diffraction (XRD) analysis result of the sample of FIG. 3;

FIG. 7 is a fourier diffractogram of the sample of FIG. 3; and

FIG. 8 is a cross-sectional view of a stack structure comprising a LaAlO film according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

A method of forming a thin film, e.g., LaAlO film, structure and a stack structure comprising the thin film according to example embodiments will now be described more fully with reference to the accompanying drawings in which example embodiments are shown. In the drawings, the thicknesses of layers and regions are exaggerated for clarity. Like numbers refer to like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

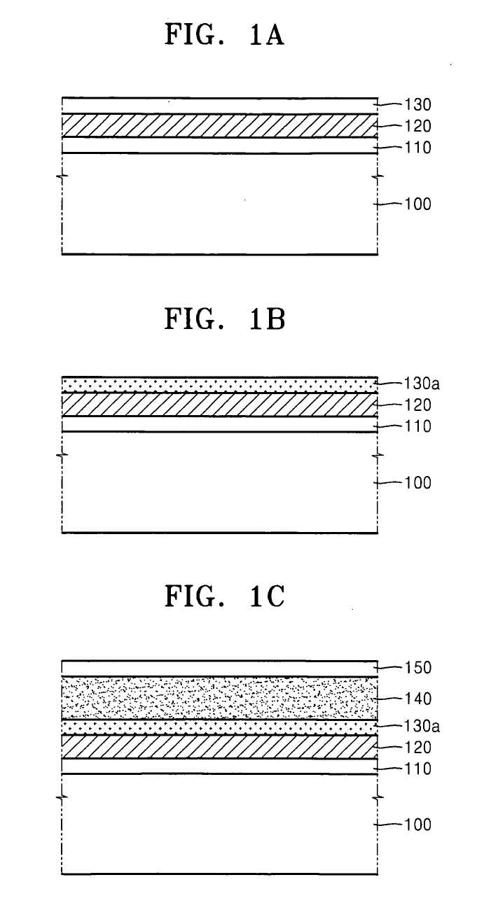

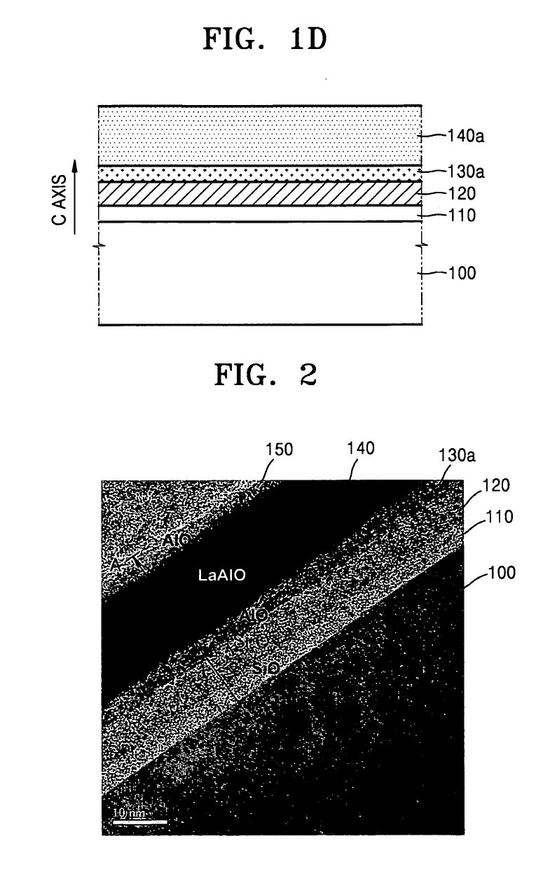

FIGS. 1A-1D are cross-sectional views illustrating a method of forming a LaAlO film structure according to example embodiments. Referring to FIG. 1A, a silicon oxide film (SiOₓ) 110 and a silicon nitride film (SiₓN_{y}) 120 may be sequentially formed on a predetermined or given substrate, for example, a silicon substrate 100. The silicon oxide film 110 may be formed using a thermal oxidation process, and the silicon nitride film 120 may be formed using a chemical vapor deposition (CVD) method. The silicon nitride film 120 may be an amorphous film.

An AlₓO_{y} film 130 may be formed on the silicon nitride film 120. The AlₓO_{y} film 130 may be formed to a thickness of about 5 nm using a CVD method, a physical vapor deposition (PVD) method and/or an atomic layer deposition (ALD) method. The AlₓO_{y} film 130 may be an amorphous state. The AlₓO_{y} film 130 may be annealed at a relatively high temperature. As a result, the AlₓO_{y} film 130 may be transformed to a γ-Al₂O₃ film 130a as depicted in FIG. 1B. The annealing of the AlₓO_{y} film 130 may be performed in a temperature range of about 700° C. to about 1200° C., e.g., at about 900° C. under a nitrogen atmosphere. The γ-Al₂O₃ film 130a may be a polycrystal film having a cubic crystal structure, and may be a seed layer or a template layer required for crystallizing a LaAlO film 140 in a subsequent process.

Referring the FIG. 1C, the LaAlO film 140 may be formed on the γ-Al₂O₃ film 130a. A thickness of the LaAlO film 140 may be in the range of about 20 nm to about 30 nm. The LaAlO film 140 may be deposited using a predetermined or given method, for example, a CVD method, a PVD method and/or a ALD method. The LaAlO film 140 may be an amorphous film, and the content of La in the LaAlO film 140 may be greater than that of Al. The content of La and Al may be controlled according to the forming conditions of the LaAlO film 140. A ratio La to Al (La/Al) in the LaAlO film 140 may approximately satisfy the relationship of about 1<(La/Al)≦about 3.

A capping film 150 may be formed on the LaAlO film 140. The capping film 150 may be an amorphous AlₓO_{y} film, however, the capping film may also be other films. The capping film 150 may have a thickness of about 5 nm to about 10 nm. Operations for forming the LaAlO film 140 and the capping film 150 may be performed in-situ. The capping film 150 may prevent or reduce moisture from penetrating into the LaAlO film 140. Forming the capping film 150 is optional, and another film may further be formed on the capping film 150.

The resulting product, on which the capping film 150 is formed, may be annealed. As a result, as depicted in FIG. 1D, a LaAlO film 140a (an epitaxial LaAlO film) identical to an epitaxially grown LaAlO film may be formed. The resultant product may be annealed in a temperature range from about 800° C. to about 1000° C., e.g., about 900° C. The epitaxial LaAlO film 140a may have a crystal structure which is prefer-oriented in a C axis, for example, a perpendicular direction to the silicon substrate 100 through the annealing of the resultant product. This is the principle of forming the epitaxial LaAlO film 140a.

When annealing the LaAlO film 140, at least a portion of the capping film 150 may be intermixed with the LaAlO film 140. For example, one epitaxial LaAlO film 140a may be formed by inter-mixing the entire capping film 150 with the LaAlO film 140 during annealing. Also, a portion of the γ-Al₂O₃ film 130a may be intermixed with the LaAlO film 140 during annealing. Therefore, if the capping film 150 is an amorphous AlₓO_{y} film, the Al content in the epitaxial LaAlO film 140a may be greater than that of Al in the LaAlO film 140. Because the content of Al in the LaAlO film 140 increases during annealing, in order to stably crystallize the LaAlO film, the LaAlO film 140 of FIG. 1C may be originally formed richer in La.

However, if another material that may perform the same function as the amorphous AlₓO_{y} film is used as the capping film 150, the LaAlO film 140 of FIG. 1C may be formed to not be rich in La. In the operation of FIG. 1C, the initial La/Al composition in the LaAlO film 140 may be controlled. If the capping film 150 is an AlₓO_{y} film, the composition of the epitaxial LaAlO film 140a may be controlled by controlling the composition and thickness of the capping film 150.

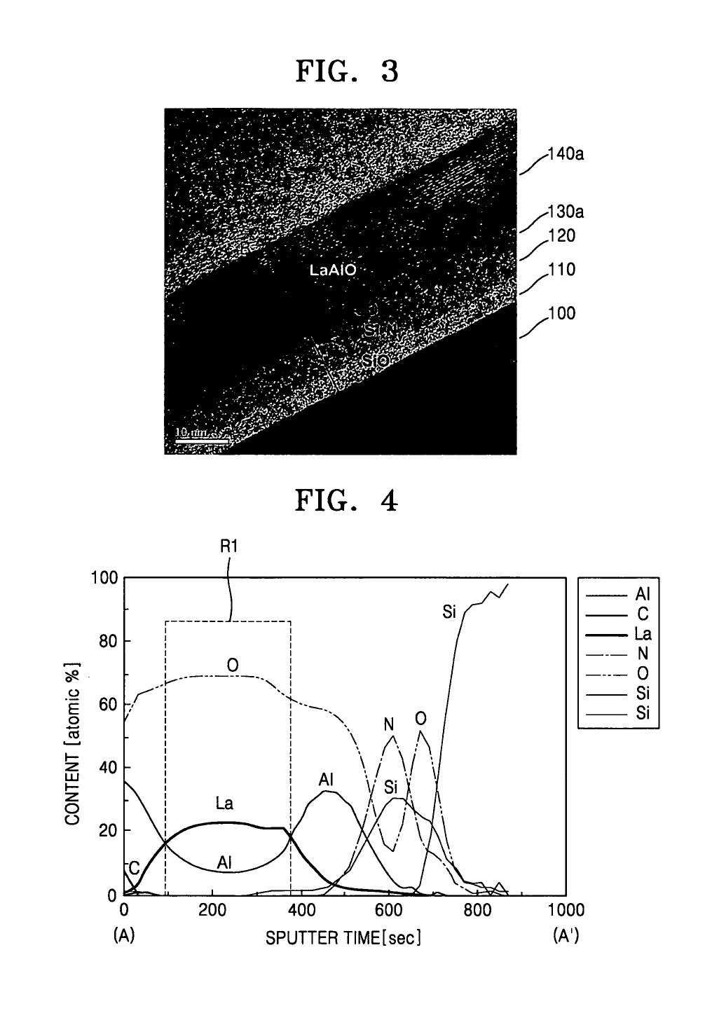

FIG. 2 is a transmission electron microscope (TEM) image of a resultant product of FIG. 1C, and FIG. 3 is a TEM image of a resultant product of FIG. 1D, for example, a TEM image taken of the sample of FIG. 2 after the sample is annealed at about 900° C. Like reference numerals indicate identical elements in FIGS. 1A-3.

Referring to FIGS. 2 and 3, the image of FIG. 2 may include the capping film 150, however, the image of FIG. 3 does not include the capping film 150. Also, crystal texture is shown in the epitaxial LaAlO film 140a of FIG. 3, however, not in the LaAlO film 140 of FIG. 2. FIGS. 2 and 3 indicate that the capping film 150 and the LaAlO film 140 are intermixed with each other due to annealing after forming the capping film 150, and thus, the epitaxial LaAlO film 140a may be formed.

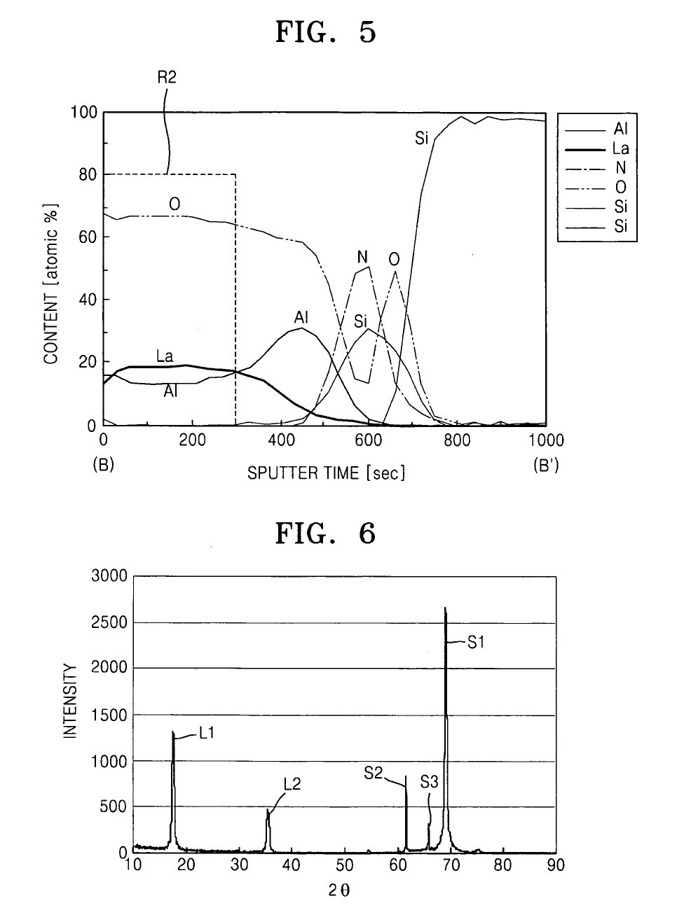

FIG. 4 is a graph showing an auger electron spectroscopy (AES) analysis result of the resultant product of FIG. 1C, and FIG. 5 is a graph showing an AES analysis result of the resultant product of 1D. FIG. 4 shows the result of analysis along line A-A′ of FIG. 2, and FIG. 5 shows the result of analysis along line B-B′ of FIG. 3. In FIGS. 4 and 5, horizontal axes indicate sputtering time to cut along predetermined or given lines in each resultant product, and vertical axes indicate the content of constituents measured along predetermined or given lines in each of the resultant products.

In FIGS. 4 and 5, a first region R1 and a second region R2, respectively, correspond to the LaAlO film 140 of FIG. 2 and the epitaxial LaAlO film 140a of FIG. 3. Referring to the first region R1 of FIG. 4, if the La content is x1 and the Al content is y1 in the LaAlO film 140, the ratio of x1/y1 may be about 2.2.

Referring to the second region R2 of FIG. 5, if La content is x2 and Al content is y2 in the epitaxial LaAlO film 140a, the ratio of x2/y2 may be about 1.4. From the results of FIGS. 4 and 5, the Al content in the epitaxial LaAlO film 140a increases due to annealing performed after forming the capping film 150. Also, if the compositions of La and Al in the LaAlO film 140 and the composition and thickness of the capping film 150 are controlled, the ratio x2/y2 may be closer to about 1.

FIG. 6 is a graph showing an X-ray diffraction (XRD) analysis result of the resultant product of FIG. 1D. In FIG. 6, there are first and second peaks L1 and L2 generated due to the epitaxial LaAlO film 140a besides three peaks S1, S2, and S3 generated due the silicon substrate 100. The first and second peaks L1 and L2 are detected when 2θ is about 17.7° and about 35.5° respectively. According to Bragg's equation, a distance between surfaces corresponding to the first peak L1 is about 5.0 Å, and a distance between planes corresponding to the second peak L2 is about 2.5 Å. Accordingly, the plane corresponding to the first peak L1 and the plane corresponding to the second peak L2 are parallel to each other. The result of FIG. 6 shows that the epitaxial LaAlO film 140a of FIG. 3 is a crystal uniformly oriented in a C axis, for example, a direction perpendicular to the silicon substrate 100.

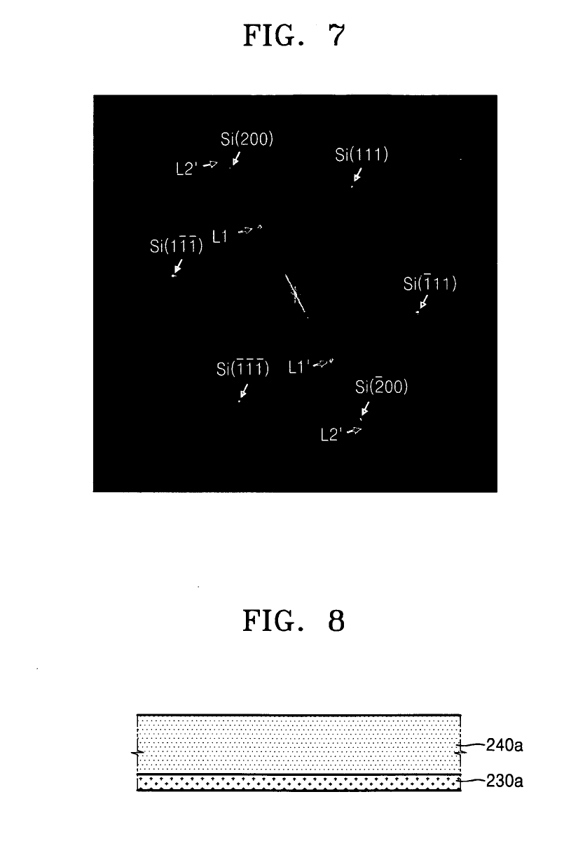

FIG. 7 is a fourier diffractogram of the resultant product of FIG. 1D obtained using a TEM. Planes are shown as spots in the fourier diffractogram. In FIG. 7, there are six spots generated due to the planes of the silicon substrate 100, and four spots L1′ and L2′ generated due to the planes of the epitaxial LaAlO film 140a. In FIG. 7, the planes of the silicon substrate 100 are (200), ( 2̅00), (111), ( 1̅11), ( 1̅1̅1̅), and (1 1̅1̅). The planes of the epitaxial LaAlO film 140a are L1′ and L2′ which respectively correspond to the first and second peaks L1 and L2 of FIG. 6.

Referring to FIG. 7, the planes L1′ and L2′ corresponding to the first and second peaks L1 and L2 are parallel to the (100) plane of the silicon substrate 100, which denotes that the epitaxial LaAlO film 140a is uniformly oriented in a direction perpendicular to the (100) plane of the silicon substrate 100. The distance between the planes shown in FIG. 7 coincides with the distance between the planes obtained from FIG. 6.

In example embodiments described above, the epitaxial LaAlO film 140a may be formed using a crystalline AlₓO_{y} film, for example, the γ-Al₂O₃ film 130a formed on the amorphous silicon nitride film 120 as a seed layer or a template layer. The γ-Al₂O₃ film 130a may be formed by annealing the amorphous AlₓO_{y} film 130. The amorphous AlₓO_{y} film 130 may be formed not only on the silicon nitride film 120 but also on films made of another material. Thus, example embodiments may be used to form an epitaxial LaAlO film regardless of the kind of substrate or base layer.

As described above, when example embodiments are used, because the epitaxial LaAlO film may be formed regardless of the kind of substrate or base layer, essential constituent elements of a stack structure comprising a LaAlO film according to example embodiments are a crystalline AlₓO_{y} film and an epitaxial LaAlO film formed on the crystalline AlₓO_{y} film. Other constituent elements, for example, a substrate and a capping film, are optional and variable.

FIG. 8 is a cross-sectional view of a stack structure comprising a LaAlO film according to example embodiments. Referring to FIG. 8, an epitaxial LaAlO film 240a may be formed on a crystalline AlₓO_{y} film 230a. The AlₓO_{y} film 230a may be a γ-Al₂O₃ film. The epitaxial LaAlO film 240a may be identical to the epitaxial LaAlO film 140a of FIG. 1D, which may be formed using the method according to example embodiments. A capping film (not shown) may further be formed on an upper surface of the epitaxial LaAlO film 240a. The capping film may be an amorphous AlₓO_{y} film, however, the capping film may also be films made of another material. Also, a predetermined or given lower structure (not shown) may further be formed on a lower surface of the AlₓO_{y} film 230a.

As described above, in example embodiments, an epitaxial LaAlO film may be formed using a crystalline AlₓO_{y} film crystallized from an amorphous AlₓO_{y} film as a seed layer. Thus, when example embodiments are used, the epitaxial LaAlO film may be formed regardless of the kind of substrate or base layer.

Thus, the epitaxial LaAlO film according to example embodiments may replace a conventional single crystal LaAlO₃ substrate and may have a relatively wide range of applicability compared to the conventional single crystal LaAlO₃ substrate. Also, considering that the conventional single crystal LaAlO₃ substrate is more expensive than a silicon substrate or a glass substrate, the use of the epitaxial LaAlO film according to example embodiments may reduce manufacturing costs.

While example embodiments have been particularly shown and described with reference to example embodiments, it will be understood by those of ordinary skill in the art that various changes in form and details may be made therein without departing from the spirit and scope of the following claims.

What is claimed is:

1. A method of forming a thin film structure comprising:
forming a crystalline AlₓO_{y} film;
forming a LaAlO film on the crystalline AlₓO_{y} film; and
crystallizing the LaAlO film by annealing the LaAlO film.

2. The method of claim 1, wherein the AlₓO_{y} film is a γy-Al₂O₃ film.

3. The method of claim 1, wherein the AlₓO_{y} film is formed by annealing an amorphous AlₓO_{y} film.

4. The method of claim 3, wherein the amorphous AlₓO_{y} film is annealed in a temperature range from about 700° C. to about 1200° C.

5. The method of claim 1, wherein the content of La is greater than that of Al in the LaAlO film.

6. The method of claim 1, further comprising:
forming a capping film on the LaAlO film before annealing the LaAlO film, but after forming the LaAlO film.

7. The method of claim 6, wherein forming the LaAlO film and forming the capping film includes performing an in-situ process.

8. The method of claim 6, wherein the AlₓO_{y} film is a first AlₓO_{y} film and the capping film is a second AlₓO_{y} film.

9. The method of claim 8, wherein the second AlₓO_{y} film is an amorphous AlₓO_{y} film.

10. The method of claim 1, wherein the annealing is performed in a temperature range of about 800° C. to about 1000° C.

11. The method of claim 8, wherein at least a portion of the second AlₓO_{y} film and the LaAlO film are intermixed during annealing.

12. The method of claim 9, wherein at least a portion of the second AlₓO_{y} film and the LaAlO film are intermixed during annealing.

13. A stack structure comprising:
a crystalline AlₓO_{y} film; and
a LaAlO film formed on the AlₓO_{y} film,
wherein the LaAlO film is identical to an epitaxially grown LaAlO film.

14. The stack structure of claim 13, wherein the AlₓO_{y} film is a γ-Al₂O₃ film.

15. The stack structure of claim 13, further comprising:
a capping layer on the LaAlO film.

16. The stack structure of claim 15, wherein the AlₓO_{y} film is a first AlₓO_{y} film and the capping film is a second AlₓO_{y} film.

17. The stack structure of claim 16, wherein the second AlₓO_{y} film is an amorphous AlₓO_{y} film.

18. The stack structure of claim 13, wherein the crystalline AlₓO_{y} film is formed on a nitride film.
